(19) United States
(12) Patent Application Publication
(10) Pub. No.: US 2005/0162216 A1
(43) Pub. Date: Jul. 28, 2005

(54) Semiconductor integrated circuit device

(75) Inventor: Goro Ueda, Nukata-gun (JP)

Correspondence Address: POSZ LAW GROUP, PLC, 12040 SOUTH LAKES DRIVE, SUITE 101, RESTON, VA, 20191, US

(73) Assignees: DENSO CORPORATION; TOYOTA JIDOSHA KABUSHIKI KAISHA

(21) Appl. No.: 11/038,218

(22) Filed: Jan. 21, 2005

(30) Foreign Application Priority Data
Jan. 27, 2004 (JP) 2004-18391

(51) Int. Cl. H03B 1/00; H03K 3/00

(52) U.S. Cl. 327/540

(57) ABSTRACT

A semiconductor integrated circuit device for a power source capable of being expanded to cope with an increase or decrease in the load includes an outer transistor attached to the outer side of an IC, and a transistor incorporated thereon simultaneously operated to enhance the current output capability of a linear regulator when a load is great. A control circuit controls the transistor to produce a constant voltage, and controls the outer transistor to control the current ratio of the current flowing into the transistor and the current flowing into the outer transistor. An over-current detecting circuit detects, at one time, the collector currents of the transistors flowing into the output line, and executes an over-current protection control based on the detected values.

### CROSS REFERENCE TO RELATED APPLICATION

This application is based upon, claims the benefit of priority of, and incorporates by reference the contents of, Japanese Patent Application No. 2004-18391 filed on Jan. 27, 2004.

### FIELD OF THE INVENTION

The present invention relates to a semiconductor integrated circuit device for a power source that feeds a predetermined voltage or current to a load.

### BACKGROUND OF THE INVENTION

In some microcomputer systems, an IC mounted on a substrate often incorporates a power source circuit which also feeds electric power to external circuits such as other ICs and sensors. FIG. 10 schematically illustrates a constitution in which ICs 1 and 4 incorporate power source circuits 2 and 5. The IC 1 feeds electric power to external circuits 7a, 7b and 7c through a power source line 3, and IC 4 feeds electric power to external circuits 7d, 7e and 7f through a power source line 6.

JP-A-7-141065 discloses an IC equipped with a halting terminal for halting the function of a power source circuit incorporated in the IC and a function-halting circuit for halting the function of the power source circuit by grounding the halting terminal. FIG. 11A illustrates a concrete system constitution thereof, wherein an IC 8 incorporates a power source circuit 9 which feeds electric power to external circuits 7a, 7b, 7c through a power source line 10.

When the current capacity and the voltage precision required by the external circuits 7a, 7b, 7c are varied, the function of the power source circuit 9 is halted by using a halt signal and, instead, the electric power is fed from a power source circuit 12 incorporated in an IC 11. FIG. 11B illustrates a concrete circuit constitution of the power source circuit 9. When the halt signal of the L level is output, a switch 13 is turned off to halt the supply of current to an operational amplifier 14 and, whereby the transistors Q1 and Q2 are turned off.

In the system shown in FIG. 10, the power source circuit 2 in the IC 1 and the power source circuit 5 in the IC 4 are controlled independently of each other. When the system is considered as a whole, therefore, the circuits for controlling the power source circuits are duplicated, causing the circuit scale and the substrate area to be increased as a whole, which is disadvantageous from the standpoint of cost. Further, when the current capacity has changed in the external circuits 7a to 7f, the external circuits 7a to 7f supported by the power source circuits 2 and 5 must be varied, making it necessary to vary the substrate pattern and to vary the design of the ICs 1 and 4.

In the system shown in FIG. 11A, the power source circuit 9 in the IC 8 and the power source circuit 12 in the IC 11 are also controlled independently of each other, and the electric power is never fed simultaneously, causing duplication of the circuit for controlling the power source circuits. Therefore, the circuit scale and the substrate area are increased as a whole, which is disadvantageous from the standpoint of cost.

### SUMMARY OF THE INVENTION

In view of the above circumstances, it is an object to provide a semiconductor integrated circuit device for a power source, which can be expanded to cope with an increase or decrease in the load, to thereby minimize the scale of the circuit for controlling the power source circuit.

According to a first aspect, a semiconductor integrated circuit device for a power source incorporates an output transistor for producing a voltage or a current for the load, and a drive control circuit thereof. When, for example, the device is for a constant-voltage power source, the control circuit detects the output voltage to control the voltage by feedback to thereby control the output transistor so that the output voltage for the load comes into agreement with a target voltage. Further, when the device is for a constant-current source, the control circuit detects the output current to control the current by feedback to thereby control the output transistor that the output current for the load comes into agreement with a target current.

When the current fed to the load is smaller than a rated current of the output transistor that is incorporated and the loss of the output transistor is smaller than an allowable value of the semiconductor integrated circuit device, the semiconductor integrated circuit device feeds the electric power by itself to the load. On the other hand, when the load becomes too great to exceed the above limitation, an output transistor is attached to the outer side of the semiconductor integrated circuit device so that the output transistor that is incorporated and the output transistor that is attached to the outer side operate in parallel to feed a large electric power to the load.

In this case, the control circuit controls the output transistor that is attached to the outer side, so that a predetermined current ratio is maintained by the current flowing into the incorporated output transistor and the current flowing into the output transistor that is attached to the outer side. Therefore, if the voltage or the current is controlled by feedback for the incorporated output transistor only, the follow-up control is carried out to accomplish the target voltage or the target current. As a result, the two output transistors are stably controlled by using a single control circuit without being interfered by each other, thereby making it possible to decrease the circuit scale of the power source (particularly, drive control circuit) when the system as a whole is considered, in comparison to the conventional constitution according to which the power sources have to be dispersed.

According to a second aspect, the current flowing into the incorporated output transistor is detected by a first current detecting circuit and the current flowing into the output transistor attached to the outer side is detected by a second current detecting circuit. As the current detecting circuits, there are used, for example, resistance circuits. An error amplifier circuit sends a drive signal to control terminals (base, gate) of the output transistor attached to the outer side, so that the ratio of the detected currents becomes a predetermined ratio.

According to a third aspect, an over-current protection signal is formed based on an added current of an output current of the incorporated output transistor and an output current of the output transistor that is attached to the outer side. Since the ratio of the current flowing into the incorporated output transistor and the current flowing into the output transistor attached to the outer side has been controlled to be a predetermined ratio, it does not happen that the current flows in a concentrated manner into either one of them. Even if the two currents are detected at one time, over-currents flowing into the two output transistors can be reliably detected. Besides, there is no need to provide the over-current detecting circuit for each output transistor, and the circuit scale can be decreased. Here, the over-current detecting circuit may have hysteresis characteristics.

According to a fourth aspect, an over-current protection signal is formed based on at least either a current flowing into the incorporated output transistor or a current flowing into the output transistor attached to the outer side. The ratio of the current flowing into the incorporated output transistor and the current flowing into the output transistor attached to the outer side has been controlled to be a predetermined ratio. Therefore, if the over-current is detected for at least either one output transistor, the other output transistor, too, is protected from an over-current. Therefore, there is no need of providing the over-current detecting circuit for each output transistor, and the circuit scale can be decreased.

### BRIEF DESCRIPTION OF THE DRAWINGS

The above and other objects, features and advantages of the present invention will become more apparent from the following detailed description made with reference to the accompanying drawings:

FIG. 1 is a diagram illustrating the electric constitution of a linear regulator according to a first embodiment of the invention;

FIG. 2 is a diagram corresponding to FIG. 1 according to a second embodiment;

FIG. 3 is a diagram corresponding to FIG. 1 according to a third embodiment;

FIG. 4 is a diagram corresponding to FIG. 1 according to a fourth embodiment;

FIG. 5 is a diagram corresponding to FIG. 1 according to a fifth embodiment;

FIG. 6 is a diagram corresponding to FIG. 1 according to a sixth embodiment;

FIG. 7 is a diagram corresponding to FIG. 1 according to a seventh embodiment;

FIG. 8 is a diagram corresponding to FIG. 1 according to an eighth embodiment;

FIG. 9 is a diagram corresponding to FIG. 1 according to a ninth embodiment;

FIG. 10 is a diagram illustrating the electric constitution of a power source according to a prior art; and

FIG. 11A is a diagram corresponding to FIG. 10; and

FIG. 11B is a diagram illustrating the electric constitution of the power source circuit.

### DESCRIPTION OF THE PREFERRED EMBODIMENTS

### First Embodiment

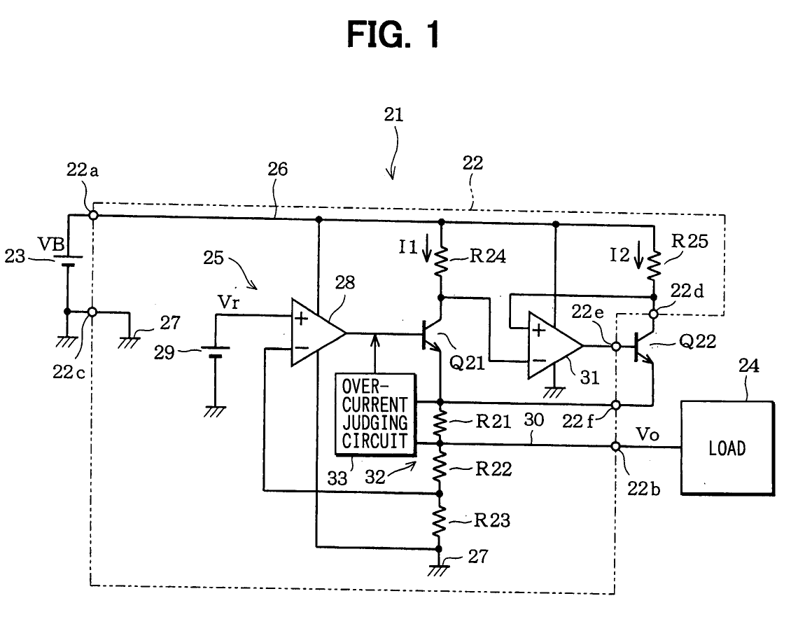

A first embodiment will now be described with reference to FIG. 1.

FIG. 1 is a diagram illustrating the circuit constitution of a linear regulator. The linear regulator 21 is a constant-voltage power source of a series regulator system, and is constituted by an IC 22 (semiconductor integrated circuit device) for a power source and, as required, an NPN-type transistor Q22 (corresponds to the outer output transistor attached to the outer side) attached to the outer side of the IC 22.

A terminal 22a of the IC 22 is a power source input terminal to which is connected a high potential side terminal of an external DC power source 23 such as a battery, and a terminal 22b is a power source output terminal which produces a constant voltage Vo to an external load 24. A terminal 22c of the IC 22 is a ground terminal, and terminals 22d, 22e and 22f are connected to the collector, base and emitter of the transistor Q22. The linear regulator 21 is mounted on a substrate that constitutes, for example, a microcomputer system. In this case, the load 24 is another IC or the like mounted on the same substrate.

Next, described below is an internal constitution of the IC 22.

The IC 22 is constituted by an NPN-type transistor Q21 (corresponds to the output transistor that is incorporated) and a control circuit 25 (corresponds to a drive control circuit) for controlling the transistors Q21 and Q22. Any other functional circuits may be included therein. The terminals 22a and 22c are connected to power source lines 26 and 27 in the IC 22. The emitter of the transistor Q21 is connected to the terminal 22b via a resistor R21 for detecting an over-current, and the collector of the transistor Q21 is connected to the power source line 26 via a resistor R24 (corresponds to a first current detecting circuit) for detecting a current flowing into the transistor Q21. Resistors R22 and R23 constituting a voltage-dividing circuit are connected in series between the terminal 22b and the power source line 27.

An operational amplifier 28 is an error amplifier for controlling the transistor Q21, and its output terminal is connected to the base (corresponding to the control terminal) of the transistor Q21. Further, a reference voltage Vr is input from a band gap reference voltage-generating circuit 29 to a non-inverted input terminal of the operational amplifier 28, and a detected voltage is input from a common connection point (voltage-dividing point) between the resistors R22 and R23 to the inverted input terminal thereof.

Between the power source line 26 and the terminal 22d, there is connected a resistor R25 (corresponds to the second current detecting circuit) for detecting a current that flows into the transistor Q22 attached to the outer side. Further, the emitter (corresponds to the current output terminal) of the transistor Q21 and the terminal 22f (emitter of the transistor Q22 (corresponds to the current output terminal)) are connected to a common output line 30 provided with the resistor R21.

The operational amplifier 31 (corresponds to the error amplifier circuit) is an error amplifier for controlling the transistor Q22, and its output terminal is connected to the terminal 22e (base of the transistor Q22). The non-inverted input terminal of the operational amplifier 31 is connected to the terminal 22d, and the inverted input terminal thereof is connected to the collector of the transistor Q21. The operational amplifiers 28 and 31 are served with a voltage VB from the power source lines 26 and 27.

An over-current detecting circuit 32 monitors a current that flows through the output line 30, and is constituted by the resistor R21 and an over-current judging circuit 33. The over-current judging circuit 33 extracts a base current that flows from the output terminal of the operational amplifier 28 to the transistor Q21 when the voltage across the resistor R21 becomes greater than a predetermined judging voltage, and forcibly turns the transistor Q21 off.

Next, described below is the action of this embodiment.

When the current requested by the load 24 exceeds a rated current of the transistor Q21 or when the collector loss of the transistor Q21 exceeds an allowable value of the IC 22, the transistor Q22 is attached to the outer side of the IC 22, and the transistor Q21 that is incorporated and the transistor Q22 attached to the outer side are concurrently operated in parallel to enhance the current output capability of the linear regulator 21.

In this case, the control circuit 25 controls the transistor Q21 incorporated in the IC 22 to carry out the constant-voltage control operation, and controls the transistor Q22 attached to the outer side of the IC 22 to control the current ratio between the current I1 flowing into the transistor Q21 and the current I2 flowing into the transistor Q22.

The constant-voltage control in this case is a feedback control which has been known as a series regulator system. That is, when the output voltage Vo becomes lower than a target voltage, the output voltage of the operational amplifier 28 increases, the base current of the transistor Q21 increases, and the output voltage Vo is raised by an amount by which the voltage across the collector and the emitter of the transistor Q21 is lowered. Conversely, when the output voltage Vo becomes greater than the target voltage, the output voltage of the operational amplifier 28 decreases, the base current of the transistor Q21 decreases, and the output voltage Vo decreases by an amount by which the voltage across the collector and the emitter of the transistor Q21 is raised.

On the other hand, the operational amplifier 31 produces a drive signal to the base of the transistor Q22 so that the voltage across the resistor R24 becomes equal to the voltage across the resistor R25. If the resistances of the resistors R24 and R25 are denoted by R24 and R25 just like the signs thereof, the ratio I1/I2 of the current I1 flowing into the transistor Q21 and the current I2 flowing into the transistor Q22, is controlled to be equal to R25/R24. Namely, the transistors Q21 and Q22 operate integrally together and if the control circuit 25 controls the transistor Q21 to produce a constant voltage, then, the transistor Q22, too, is controlled to produce a constant voltage.

When the transistor Q22 has not been attached to the outer side, no current flows into the output line 30 from the terminal 22f and, hence, the operation becomes the same as that of the conventional series regulator provided with the transistor Q21 only as the output transistor. Therefore, irrespective of whether the transistor Q22 is attached to the outer side, the linear regulator 21 produces an output equal to a target voltage determined depending upon the reference voltage Vr and the values (voltage-dividing ratio) of the resistors R22 and R23.

The collector currents I1 and I2 of the transistors Q21 and Q22 are both output through the common output line 30. Therefore, based on the voltage across the resistor R21 provided for the output line 30, the over-current detector circuit 32 detects the collector currents I1 and I2 at one time, and effects the over-current protection control based on the detected values. The collector currents I1 and I2 of the transistors Q21 and Q22 are controlled to maintain a predetermined ratio. Therefore, it does not happen that the current flows in a concentrated manner into either the transistor Q21 or Q22. Even if the two currents I1 and I2 are detected at one time, over-currents flowing into the two output transistors Q21 and Q22 can be reliably detected.

As described above, when the output current to the load 24 is smaller than the rated current of the transistor Q21 incorporated in the IC 22 and the collector loss of the transistor Q21 is smaller than the allowable value of the IC 22, the IC 22 is capable of feeding by itself the electric power to the load 24. When the above limit is exceeded, the transistor Q22 is attached to the IC 22 on the outer side thereof to operate the incorporated transistor Q21 and the transistor Q22 attached to the outer side in parallel, thereby to feed a large electric power to the load 24 making it possible to constitute a power source that is highly expansive.

In this case, the control circuit 25 controls the transistor Q22 attached to the outer side so that a predetermined current ratio is accomplished between the current I1 flowing into the transistor Q21 and the current I2 flowing into the transistor Q22. Therefore, if the incorporated transistor Q21 only is controlled to produce a constant voltage, it is possible to produce a voltage equal to the target voltage. Namely, a single control circuit 25 stably controls the transistors Q21 and Q22 without any interference by each other. Therefore, the microcomputer system as a whole requires the power source circuit of a decreased scale.

As a result of controlling the current ratio, further, over-currents flowing into the transistors Q21 and Q22 can be reliably detected even when the current I1 flowing into the transistor Q21 and the current I2 flowing into the transistor Q22 are detected individually. Moreover, since there is no need of providing an over-current detecting circuit for each of the transistors Q21, Q22, the circuit scale of the control circuit 25 can be further decreased.

### Second to Eighth Embodiments

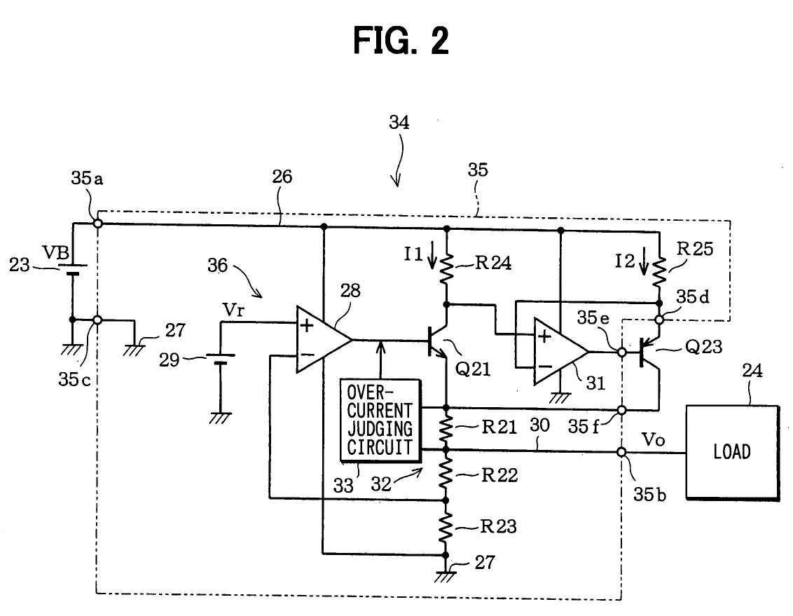

Next, the second to eighth embodiments will be described with reference to FIGS. 2 to 8. In these drawings, the same constituent portions as those of FIG. 1 are denoted by the same reference numerals.

A linear regulator 34 illustrated in FIG. 2 which is a second embodiment is constituted by an IC 35 for a power source of the series regulator system and, as required, a PNP-type transistor Q23 attached to the outer side of the IC 35. Since the transistor Q23 attached to the outer side is of the PNP type, the circuit 36 for controlling the IC 35 has the inverted input terminal of the operational amplifier 31 connected to the terminal 35d and has the non-inverted input terminal connected to the collector of the transistor Q21.

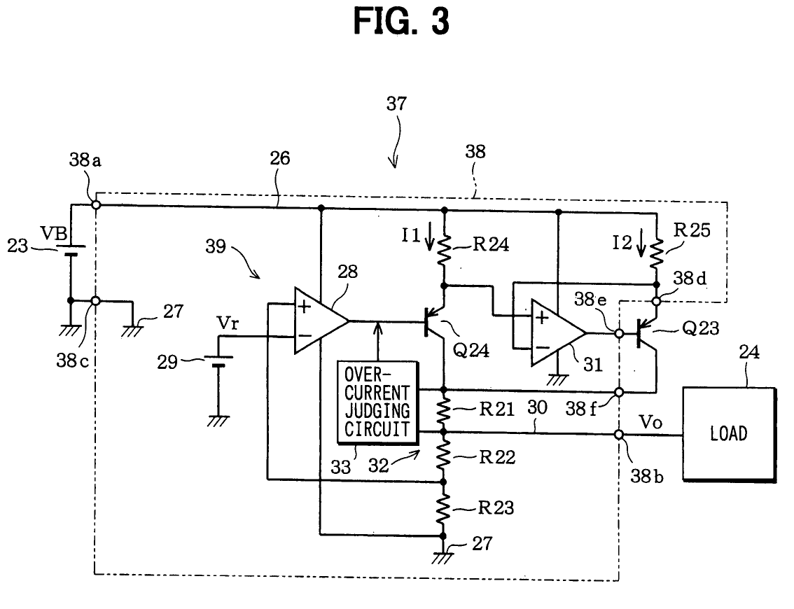

A linear regulator 37 illustrated in FIG. 3 which is a third embodiment is constituted by an IC 38 for a power source of the series regulator system and, as required, a PNP-type transistor Q23 attached to the outer side of the IC 38. Since the transistor Q24 incorporated in the IC 38 is of the PNP type, the control circuit 39 has the inverted input terminal of the operational amplifier 28 connected to the band gap reference voltage-generating circuit 29 and has the non-inverted input terminal connected to a common connection point of the resistors R22 and R23. The operational amplifier 31 is connected in the same manner as shown in FIG. 2.

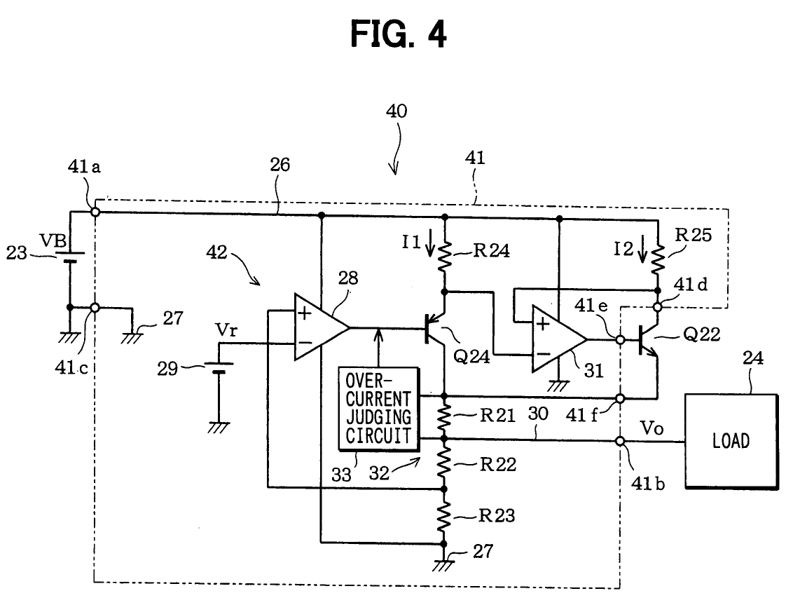

A linear regulator 40 illustrated in FIG. 4 which is a fourth embodiment is constituted by an IC 41 for a power source of the series regulator system and, as required, an NPN-type transistor Q22 attached to the outer side of the IC 41. The transistor Q24 incorporated in the IC 41 is of the PNP type, and the operational amplifiers 28 and 31 are connected in the same manner as shown in FIGS. 3 and 1.

The linear regulators 34, 37 and 40 illustrated in FIGS. 2 to 4 employ bipolar transistors as output transistors Q21 to Q24 that are incorporated or attached to the outer side, and exhibit the same action and effect as those of the linear regulator 21 illustrated in the first embodiment.

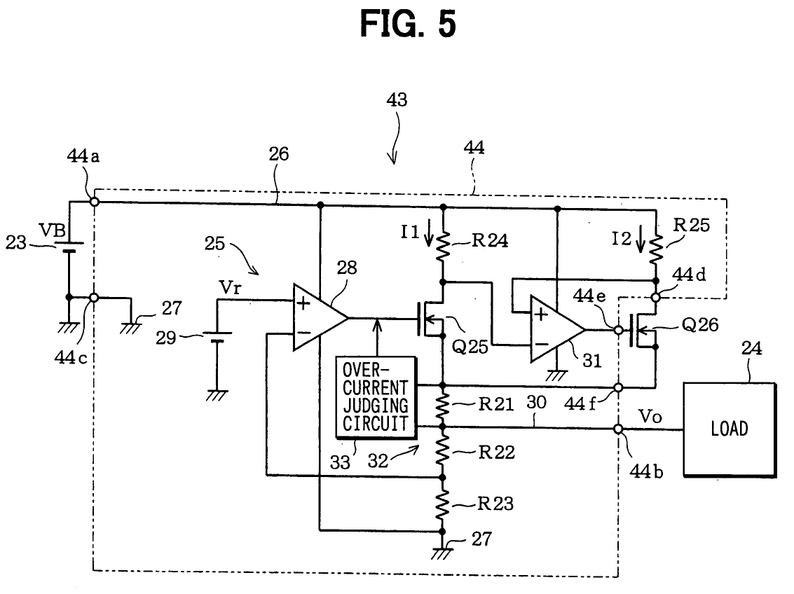

A linear regulator 43 illustrated in FIG. 5 which is a fifth embodiment is constituted by an IC 44 for a power source of the series regulator system and, as required, an N-channel MOS transistor Q26 attached to the outer side of the IC 44. The IC 44 incorporates an N-channel MOS transistor Q25 as an output transistor. The control circuit for the IC 44 is the same as the control circuit 25 shown in FIG. 1 except a difference in design.

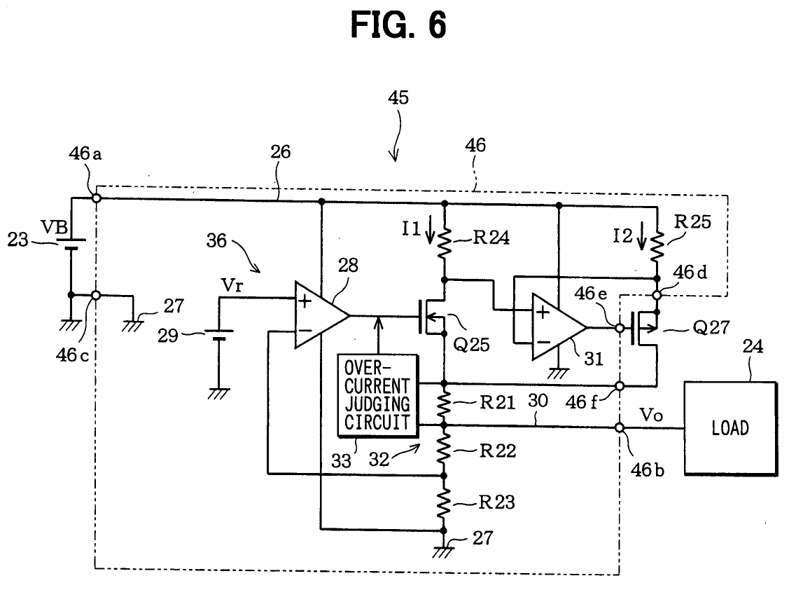

A linear regulator 45 illustrated in FIG. 6 which is a sixth embodiment is constituted by an IC 46 for a power source of the series regulator system and, as required, a P-channel MOS transistor Q27 attached to the outer side of the IC 46. The IC 46 includes a MOS transistor Q25 and a control circuit 36.

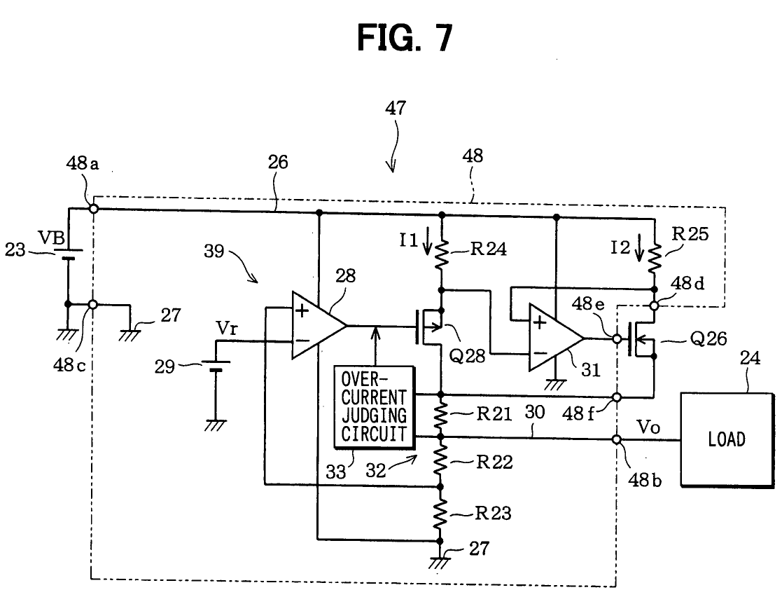

A linear regulator 47 illustrated in FIG. 7 which is a seventh embodiment is constituted by an IC 48 for a power source of the series regulator system and, as required, an N-channel MOS transistor Q26 attached to the outer side of the IC 48. The IC 48 incorporates a P-channel MOS transistor Q28 as an output transistor which is controlled by the control circuit 39.

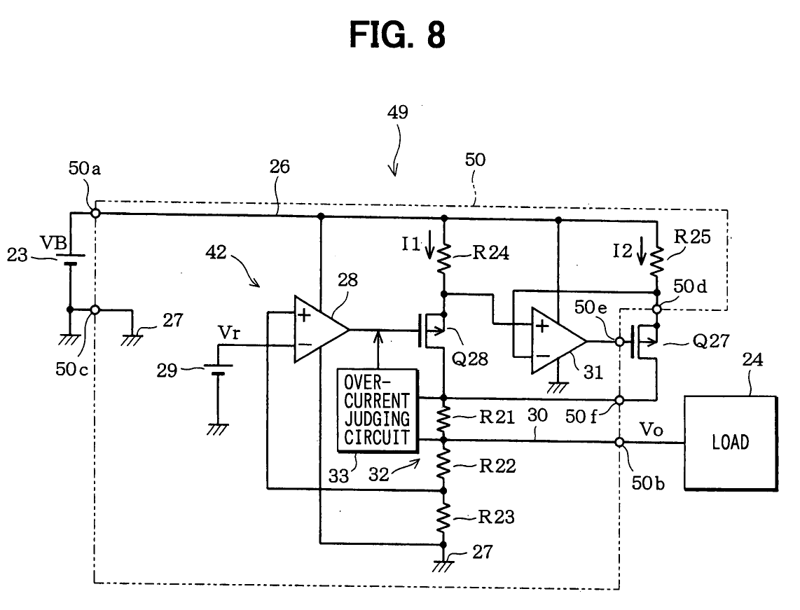

A linear regulator 49 illustrated in FIG. 8 which is an eighth embodiment is constituted by an IC 50 for a power source of the series regulator system and, as required, a P-channel MOS transistor Q27 attached to the outer side of the IC 50. The IC 50 incorporates a P-channel MOS transistor Q28 as an output transistor which is controlled by the control circuit 42.

The linear regulators 43, 45, 47 and 49 illustrated in FIGS. 5 to 8 employ MOS transistors as output transistors Q25 to Q28 that are incorporated or attached to the outer side, and exhibit the same action and effect as those of the linear regulator 21 illustrated in the first embodiment.

### Ninth Embodiment

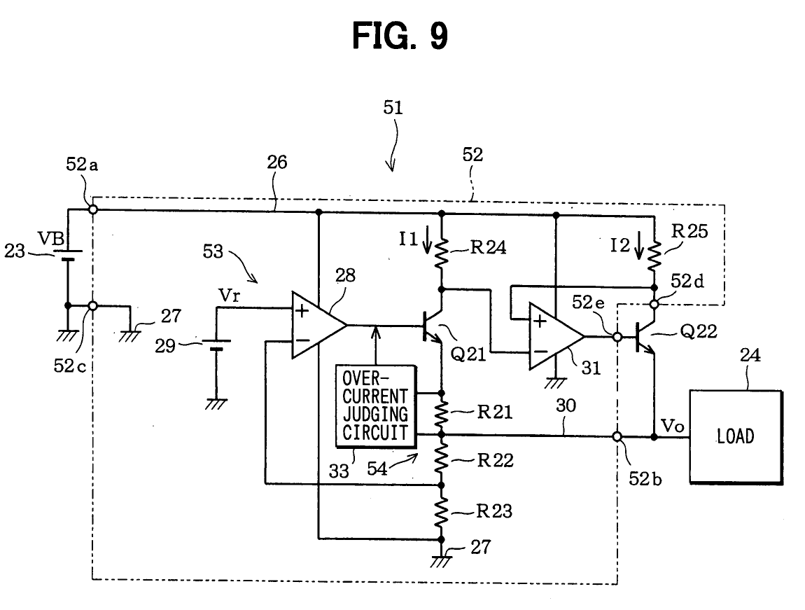

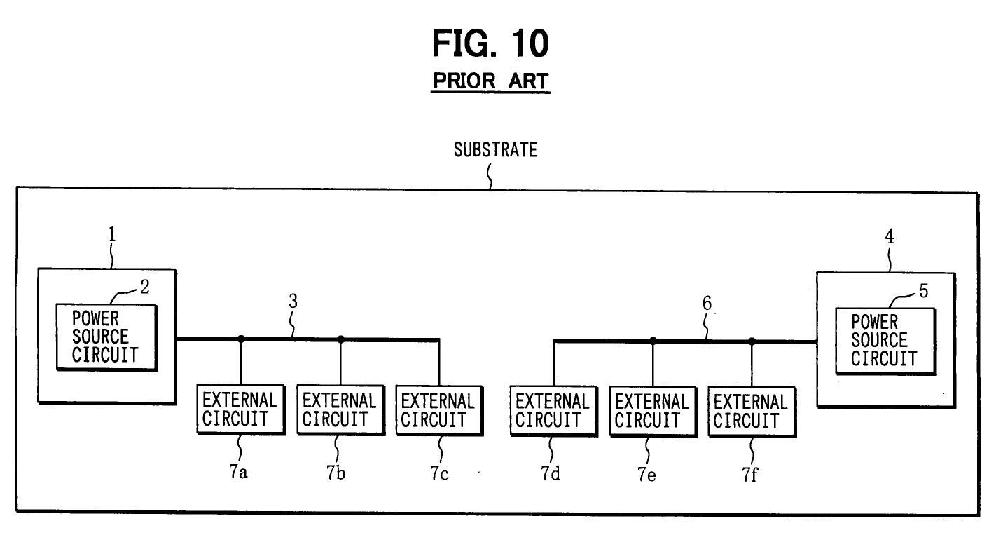

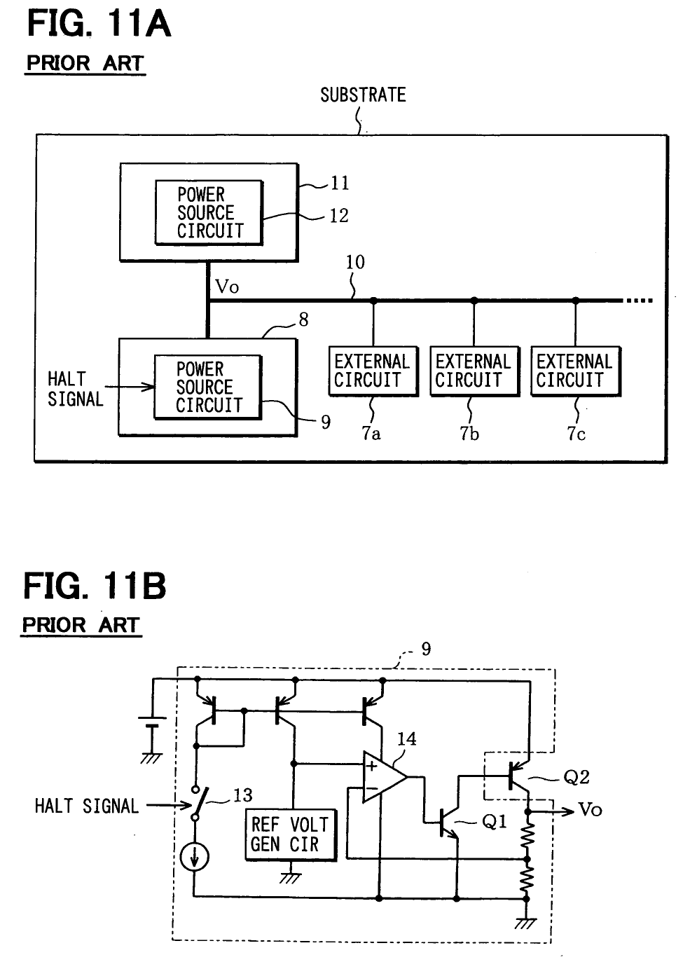

Next, a ninth embodiment will be described with reference to FIG. 9.

FIG. 9 illustrates the electric constitution of a linear regulator and in which the same constituent portions as those of FIG. 1 are denoted by the same reference numerals. The linear regulator 51 is constituted by an IC 52 for a power source of the series regulator system and, as required, a transistor Q22 attached to the outer side of the IC 52. The emitter of the transistor Q22 is connected to a terminal 52b which is an output terminal, and an over-current detecting circuit 54 provided in the control circuit 53 in the IC 52 detects only a current I1 that flows into the transistor Q21 to judge the over-current.

The current I1 flowing into the incorporated transistor Q21 and the current flowing into the transistor Q22 attached to the outer side are controlled to maintain a predetermined current ratio. Therefore, if the current flowing into the transistor Q21 is detected, the other transistor Q22, too, is protected from the over-current. Therefore, there is no need of providing the over-current detecting circuit for each of the transistors Q21 and Q22, and the scale of the circuit can be decreased like in the first embodiment.

### Other Embodiments

The present invention is not limited to only those embodiments described above and illustrated in the drawings, but can be further modified or expanded, for example, as described below.

In the above embodiments, only one output transistor was attached to the outer side. However, a plurality of transistors may be attached to the outer side. In this case, the operational amplifier (corresponding to the operational amplifier 31) and the resistor (corresponding to the resistor R25) are provided for each of the output transistors that are to be attached to the outer side, and the current ratio is controlled for each of the transistors attached to the outer side.

This can also be applied to a constant-current power source, a variable-voltage power source and to a variable-current power source. In the case of the constant-current power source and variable-current power source, the current is controlled by feedback for the incorporated output transistor to bring the output current for the load 24 into agreement with a target current. This can be further applied to the linear regulator of a shunt regulator system.

The over-current detecting circuits 32 and 54 may be provided as required. Further, the over-current detecting circuits 32 and 54 may have hysteresis characteristics.

The over-current may be detected by detecting a current flowing into the output transistor attached to the outer side instead of detecting the current flowing into the incorporated output transistor.

The description of the invention is merely exemplary in nature and, thus, variations that do not depart from the gist of the invention are intended to be within the scope of the invention. Such variations are not to be regarded as a departure from the spirit and scope of the invention.

1. A semiconductor integrated circuit device for feeding electric power to a load, comprising an output transistor and a drive control circuit for driving said output transistor, wherein the electric power is fed to said load through said output transistor, wherein said drive control circuit controls said output transistor so that an output voltage for said load comes into agreement with a target voltage or so that an output current comes into agreement with a target current, wherein, in a state in which an outer output transistor for said load is attached to an outer side, the drive control circuit controls said outer output transistor so that a current flowing into said output transistor and a current flowing into said outer output transistor maintain a predetermined ratio.

2. A semiconductor integrated circuit device according to claim 1, wherein said drive control circuit comprises:
a first current detecting circuit for detecting a current flowing into said output transistor;
a second current detecting circuit for detecting a current flowing into said outer output transistor; and
an error amplifier circuit for producing a drive signal to a control terminal of said outer output transistor based on the currents detected by said first and second current detecting circuits.

3. A semiconductor integrated circuit device according to claim 1, further comprising an over-current detecting circuit which detects a current flowing through a common output line and produces an over-current protection signal when the detected current exceeds a predetermined upper-limit value, wherein the common output line is connected to a current output terminal of said output transistor and a current output terminal of said outer output transistor.

4. A semiconductor integrated circuit device according to claim 1, further comprising an over-current detecting circuit which detects at least either a current flowing into said output transistor or a current flowing into said outer output transistor, and produces an over-current protection signal when the detected current exceeds a predetermined upper-limit value.
